(19) United States
(12) Patent Application Publication
(10) Pub. No.: US 2026/0363034 A1
(43) Pub. Date: Nov. 12, 2026

(54) SELF-ALIGNED DOUBLE-PATTERNING SIDEWALL LAYER PROCESSES FOR FABRICATING SEMICONDUCTOR DEVICES

(71) Applicant: Microsoft Technology Licensing, LLC, Redmond, WA (US)

(72) Inventor: Branislav CURANOVIC, Austin, TX (US)

(21) Appl. No.: 19/201,392

(22) Filed: May 7, 2025

(51) Int. Cl. H10P 76/40; H10P 50/28

(52) U.S. Cl. CPC H10P 76/4085; H10P 50/283

(57) ABSTRACT

Self-aligned double-patterning sidewall layer (SADP-SL) processes for fabricating semiconductor devices are described. An example SADP-SL process includes forming a first hardmask on a target layer and forming a sacrificial base layer on the first hardmask. The process includes forming a patterned second hardmask and a patterned sacrificial base layer. The process includes forming a first sidewall layer adjacent to a first side of the patterned second hardmask and a second sidewall layer adjacent to a second side of the patterned second hardmask, where each of the first sidewall layer and the second sidewall layer corresponds to a third hardmask. The process includes selectively removing each of the patterned second hardmask and the patterned sacrificial base layer. The process includes patterning the first hardmask to form a patterned first hardmask, and by patterning the target layer using the patterned first hardmask, forming self-aligned sidewall layers associated with the device.

### BACKGROUND

Traditional device fabrication processes either rely exclusively on photolithography to pattern layers or use a combination of photolithography and spacer-based processes. Although photolithography-based processes are proven and widely deployed, they suffer from several disadvantages. As an example, the critical dimensions of the device fabricated using such photolithography-based processes are limited by the capabilities of the lithographic equipment. In addition, as the critical dimensions have become increasingly smaller, the lithographic equipment has become increasingly expensive.

Device fabrication processes that rely upon a combination of photolithography and spacer-based processes also have limitations. Accordingly, there is a need for improvements to existing device fabrication processes that rely primarily on photolithographic methods.

### SUMMARY

In one example, the present disclosure relates to a self-aligned double-patterning sidewall layer (SADP-SL) process for fabricating a device. The (SADP-SL) process may include forming a first hardmask on a target layer formed on a substrate. The (SADP-SL) process may further include forming a sacrificial base layer on the first hardmask. The (SADP-SL) process may further include forming a second hardmask on the sacrificial base layer. The (SADP-SL) process may further include patterning the second hardmask and the sacrificial base layer to form a patterned second hardmask and a patterned sacrificial base layer.

The (SADP-SL) process may further include forming a first sidewall layer adjacent to a first side of the patterned second hardmask and a second sidewall layer adjacent to a second side, opposite to the first side, of the patterned second hardmask, where each of the first sidewall layer and the second sidewall layer corresponds to a third hardmask. The (SADP-SL) process may further include selectively removing each of the patterned second hardmask and any remaining patterned sacrificial base layer. The (SADP-SL) process may further include using the third hardmask, patterning the first hardmask to form a patterned first hardmask. The (SADP-SL) process may further include by patterning the target layer using the patterned first hardmask, forming self-aligned sidewall layers associated with the device.

In another aspect, the present disclosure relates to a self-aligned double-patterning sidewall layer (SADP-SL) process for fabricating a device. The (SADP-SL) process may include forming a first hardmask on a target layer formed on a substrate. The (SADP-SL) process may further include forming a sacrificial base layer on the first hardmask. The (SADP-SL) process may further include forming a second hardmask on the sacrificial base layer. The (SADP-SL) process may further include patterning the second hardmask and the sacrificial base layer to form a patterned second hardmask and a patterned sacrificial base layer.

The (SADP-SL) process may further include by performing selective atomic layer deposition forming both: (1) a first sidewall layer adjacent to a first side of the patterned second hardmask, and (2) a second sidewall layer adjacent to a second side, opposite to the first side, of the patterned second hardmask, where each of the first sidewall layer and the second sidewall layer corresponds to a third hardmask. The (SADP-SL) process may further include selectively removing each of the patterned second hardmask and any remaining patterned sacrificial base layer. The (SADP-SL) process may further include using the third hardmask, patterning the first hardmask to form a patterned first hardmask. The (SADP-SL) process may further include by patterning the target layer using the patterned first hardmask, forming self-aligned sidewall layers associated with the device.

In yet another aspect, the present disclosure relates to a self-aligned double-patterning sidewall layer (SADP-SL) process for fabricating a device. The (SADP-SL) process may include forming a first hardmask on a target layer formed on a substrate. The (SADP-SL) process may further include forming a sacrificial base layer on the first hardmask. The (SADP-SL) process may further include forming a second hardmask on the sacrificial base layer. The (SADP-SL) process may further include patterning the second hardmask and the sacrificial base layer to form a patterned second hardmask and a patterned sacrificial base layer.

The (SADP-SL) process may further include by growing a layer of a selected material forming both: (1) a first sidewall layer adjacent to a first side of the patterned second hardmask, and (2) a second sidewall layer adjacent to a second side, opposite to the first side, of the patterned second hardmask, where each of the first sidewall layer and the second sidewall layer corresponds to a third hardmask. The (SADP-SL) process may further include selectively removing each of the patterned second hardmask and any remaining patterned sacrificial base layer. The (SADP-SL) process may further include using the third hardmask, patterning the first hardmask to form a patterned first hardmask. The (SADP-SL) process may further include by patterning the target layer using the patterned first hardmask, forming self-aligned sidewall layers associated with the device.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1 shows a cross-section view of a semiconductor device during a manufacturing stage in accordance with one example;

FIG. 2 shows a cross-section view of the semiconductor device during a subsequent fabrication stage in accordance with one example;

FIG. 3 shows a cross-section view of the semiconductor device during a subsequent fabrication stage in accordance with one example;

FIG. 4 shows a cross-section view of the semiconductor device during a subsequent fabrication stage in accordance with one example;

FIG. 5 shows a cross-section view of the semiconductor device during a subsequent fabrication stage in accordance with one example;

FIG. 6 shows a cross-section view of the semiconductor device during a subsequent fabrication stage in accordance with one example;

FIG. 7 shows a cross-section view of the semiconductor device during a subsequent fabrication stage in accordance with one example;

FIG. 8 shows a cross-section view of the semiconductor device during a subsequent fabrication stage in accordance with one example;

FIG. 9 shows a cross-section view of the semiconductor device during a subsequent fabrication stage in accordance with one example;

FIG. 10 shows a cross-section view of the semiconductor device during a subsequent fabrication stage in accordance with one example;

FIG. 11 shows a cross-section view of the semiconductor device during a subsequent fabrication stage in accordance with one example;

FIG. 12 shows a cross-section view of the semiconductor device during a subsequent fabrication stage in accordance with one example;

FIG. 13 shows a cross-section view of the semiconductor device during a subsequent fabrication stage in accordance with one example;

FIG. 14 shows a cross-section view of the semiconductor device during a subsequent fabrication stage in accordance with one example;

FIG. 15 shows cross-section views of a different semiconductor device during fabrication using a spacer etch-back process;

FIG. 15 shows cross-section views of the different semiconductor device during fabrication using the spacer etch-back process;

FIG. 17 shows a flowchart of a self-aligned double-patterning sidewall layer (SADP-SL) process for fabricating a device in accordance with one example;

FIG. 18 shows a flowchart of a self-aligned double-patterning sidewall layer (SADP-SL) process for fabricating a device in accordance with one example; and

FIG. 19 shows a flowchart of a self-aligned double-patterning sidewall layer (SADP-SL) process for fabricating a device in accordance with one example.

### DETAILED DESCRIPTION

Examples described in this disclosure relate to self-aligned double-patterning sidewall layer (SADP-SL) processes for fabricating devices, including semiconductor devices. Certain examples relate to the improvement in manufacturing techniques used in the production of semiconductor devices, such as processors and memory chips. As noted earlier, traditional device fabrication processes either rely exclusively on photolithography to pattern layers or use a combination of photolithography and spacer-based processes. Although photolithography-based processes are proven and widely deployed, they suffer from several disadvantages. As an example, the critical dimensions of the device fabricated using such photolithography-based processes are limited by the capabilities of the lithographic equipment. In addition, as the critical dimensions have become increasingly smaller, the lithographic equipment has become increasingly expensive.

Device fabrication processes that rely upon a combination of photolithography and spacer-based processes also have limitations. As an example, such processes include spacer formation and spacer etch steps. The use of spacers makes the critical dimensions subject to the limitations of the steps associated with spacer formation and spacer etch steps. To address the deficiencies of traditional device fabrication steps, the examples described herein relate to self-aligned double-patterning sidewall layer (SADP-SL) processes that in some examples use the deposition and removal of various thin films to create circuit patterns on silicon. The SADP-SL processes can be used to complement and/or reduce the dependency on traditional patterning technology (photolithography), which is typically the slowest and the most expensive part of the device fabrication process. Advantages of the SADP-SL processes include increased manufacturing throughput and lowered costs without the concomitant loss of pattern fidelity.

FIG. 1 shows a cross-section view 100 of semiconductor device 10 during a fabrication stage in accordance with one example. In this example, semiconductor device 10 is shown as having a target layer 104 formed over a substrate 102 of a wafer. Substrate 102 may be a silicon layer, a stack of layers, or a semiconductor-on-insulator (SOI) substrate. Target layer 104 may be comprised of silicon or any other material that can be patterned to form semiconductor devices. Although FIG. 1 shows a certain number of layers of semiconductor device 10 arranged in a certain manner, there could be more or fewer layers arranged differently.

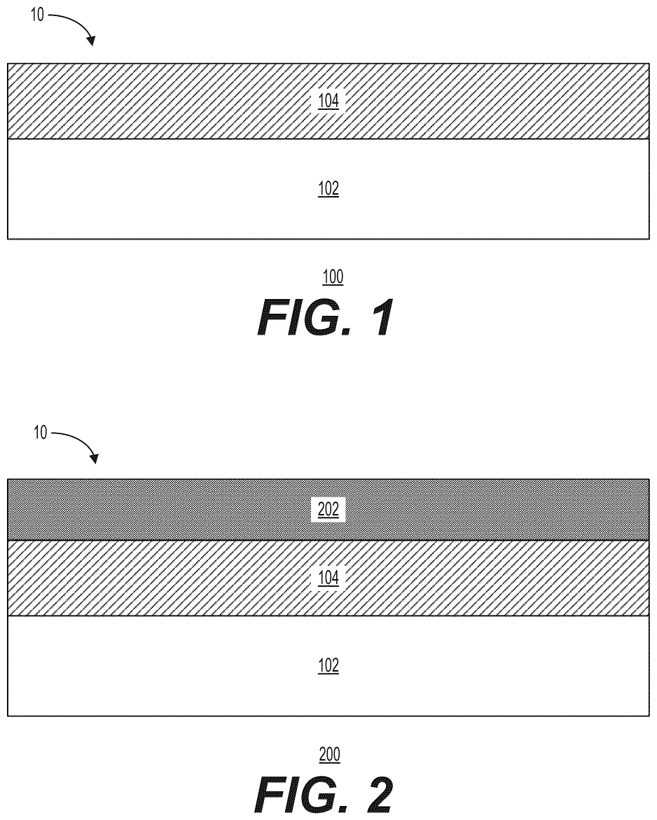

FIG. 2 shows a cross-section view 200 of the semiconductor device 10 during a subsequent fabrication stage in accordance with one example. Unless expressly indicated otherwise, the same or similar regions and structures that are shown in FIG. 2 are referred to using the same reference numbers as used in FIG. 1. As a result, such same or similar regions and structures are not described again as part of the description associated with FIG. 2. Cross-section view 200 shows the formation of a hardmask 202 over the target layer 104. Hardmask 202 can be formed by depositing appropriate materials on target layer 104 or by growing a layer on target layer 104. Hardmask 202 can be formed using materials such as silicon dioxide (SiO₂), silicon nitride (Si₃N₄), or other similar materials. Although FIG. 2 shows a certain number of layers of semiconductor device 10 arranged in a certain manner, there could be more or fewer layers arranged differently.

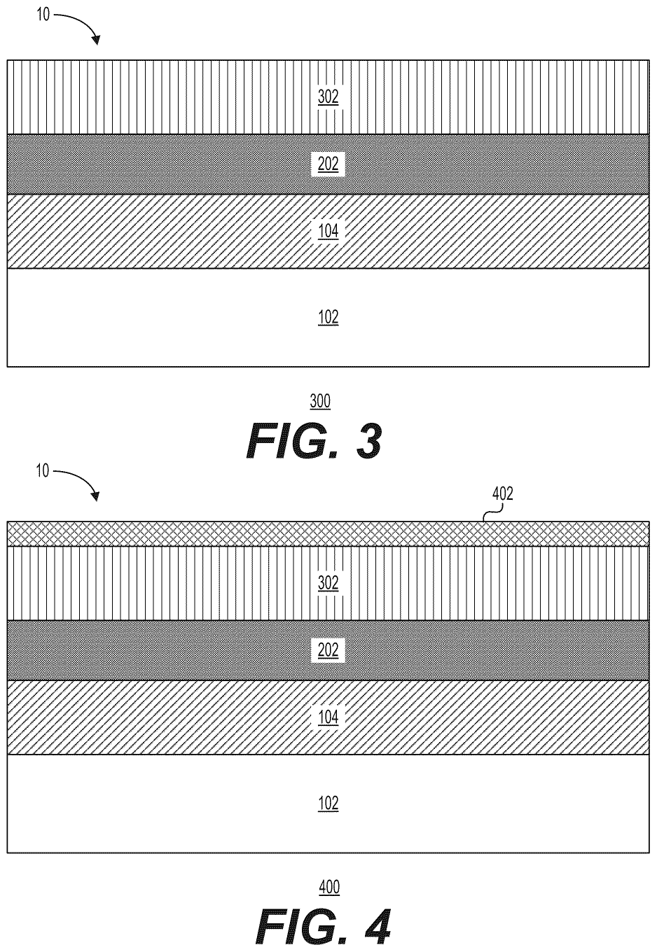

FIG. 3 shows a cross-section view 300 of the semiconductor device 10 during a subsequent fabrication stage in accordance with one example. Unless expressly indicated otherwise, the same or similar regions and structures that are shown in FIG. 3 are referred to using the same reference numbers as used in FIGS. 1 and 2. As a result, such same or similar regions and structures are not described again as part of the description associated with FIG. 3. Cross-section view 300 shows a sacrificial base layer 302 formed over hardmask 202. In this example, sacrificial base layer 302 can be formed by depositing polysilicon over hardmask 202. Although FIG. 3 shows a certain number of layers of semiconductor device 10 arranged in a certain manner, there could be more or fewer layers arranged differently.

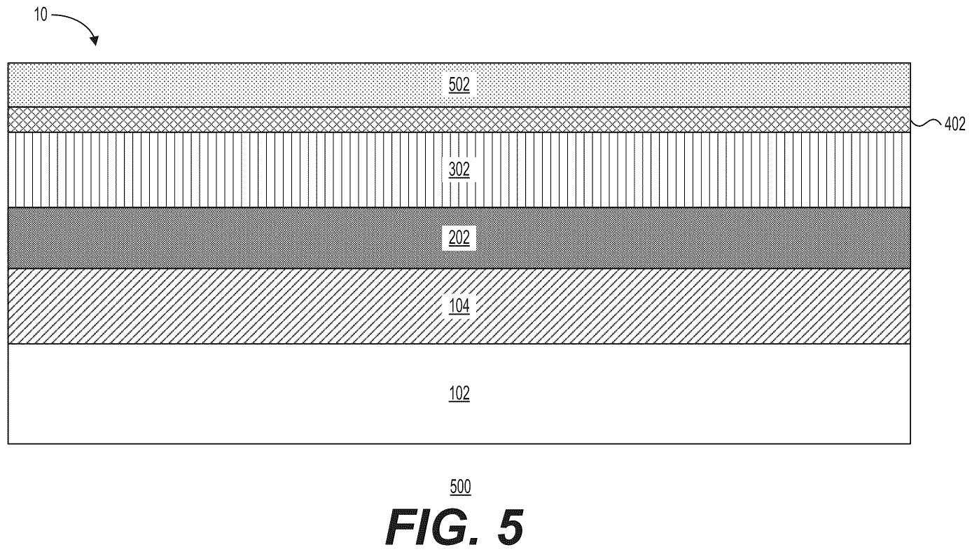

FIG. 4 shows a cross-section view 400 of the semiconductor device of FIG. 3 during a subsequent fabrication stage in accordance with one example. Unless expressly indicated otherwise, the same or similar regions and structures that are shown in FIG. 4 are referred to using the same reference numbers as used in FIGS. 1-3. As a result, such same or similar regions and structures are not described again as part of the description associated with FIG. 4. Cross-section view 400 shows the formation of hardmask 402 over sacrificial base layer 302. Hardmask 402 can be formed by depositing appropriate materials on sacrificial base layer 302 or by growing a layer on sacrificial base layer 302. Hardmask 402 can be formed using materials such as silicon dioxide (SiO₂), silicon nitride (Si₃N₄), or other similar materials. Although FIG. 4 shows a certain number of layers of semiconductor device 10 arranged in a certain manner, there could be more or fewer layers arranged differently.

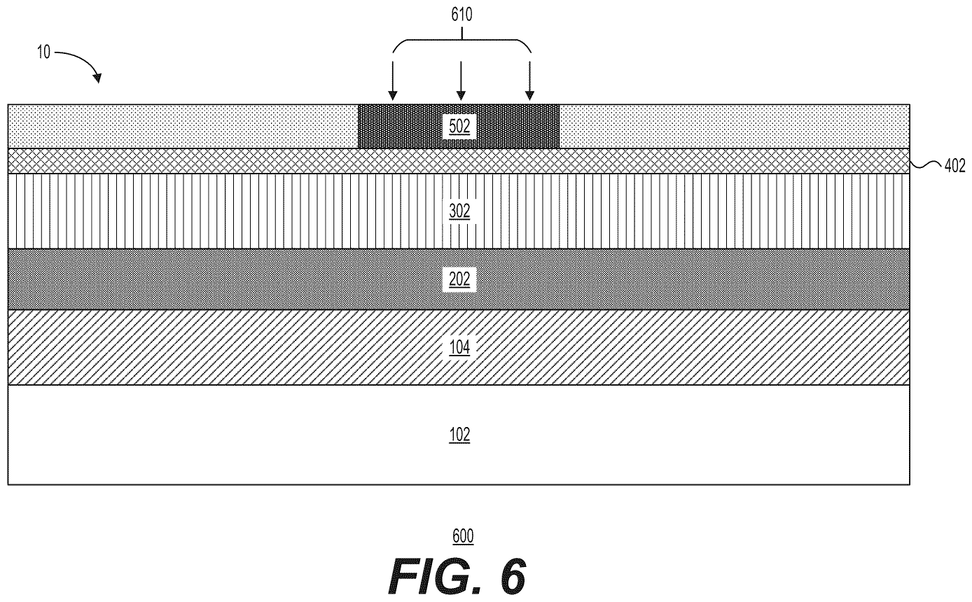

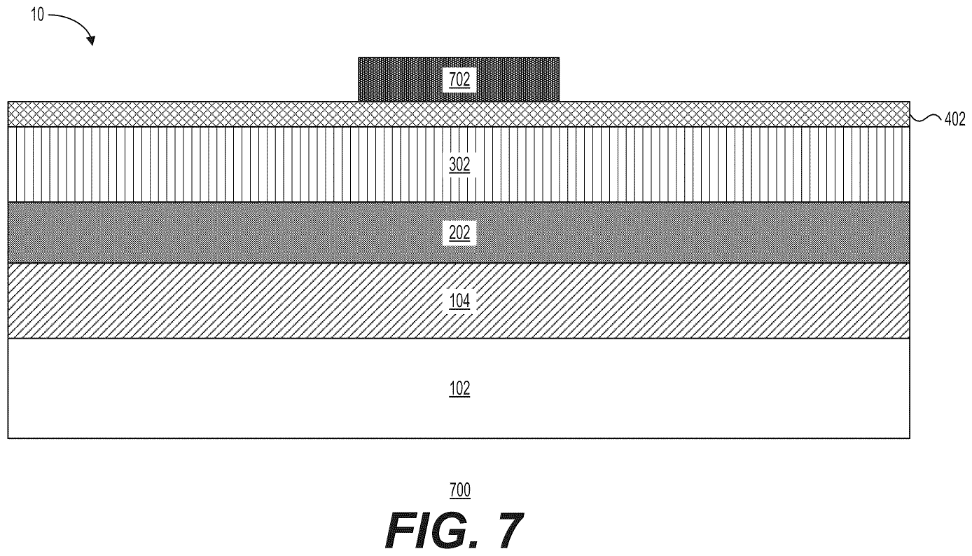

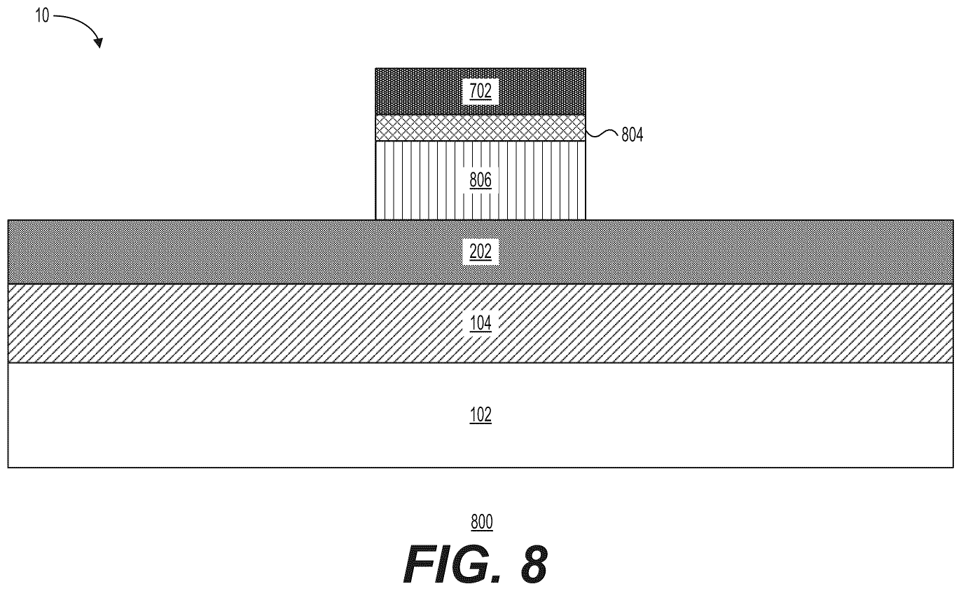

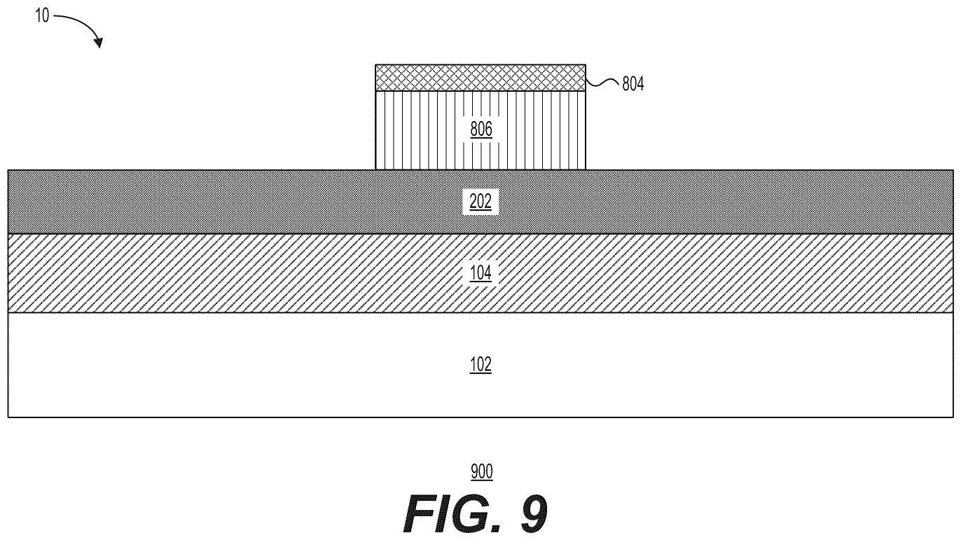

FIGS. 5-9 relate to the patterning of sacrificial base layer 302 of FIG. 3 and hardmask 402 of FIG. 4 and. FIG. 5 shows a cross-section view 500 of the semiconductor device 10 during a subsequent fabrication stage in accordance with one example. Unless expressly indicated otherwise, the same or similar regions and structures that are shown in FIGS. 5-9 are referred to using the same reference numbers as used in the previously described figures. As a result, such same or similar regions and structures are not described again as part of the description associated with FIGS. 5-9. Cross-section view 500 shows the application of photoresist 502 over hardmask 402 to enable photolithography-based processing during this fabrication stage. FIG. 6 shows a cross-section view 600 of the semiconductor device 10 of FIG. 5 during a subsequent fabrication stage in accordance with one example. This stage relates to the exposure of applied photoresist 502 using light rays 610, including ultraviolet light rays or extreme ultraviolet light rays. FIG. 7 shows a cross-section view 700 of the semiconductor device 10 of FIG. 6 during a subsequent fabrication stage in accordance with one example. Cross-section view 700 shows developed photoresist 702. As shown in FIG. 8, which shows a cross-section view 800 of the semiconductor device 10 of FIG. 7, using processes such as anisotropic etching, hardmask 402 and sacrificial base layer 302 are formed as patterned hardmask 804 and patterned sacrificial base layer 806. Moreover, as shown in cross-section view 900 of FIG. 9, after the formation of patterned hardmask 804 and patterned sacrificial base layer 806, developed photoresist 702 is stripped away.

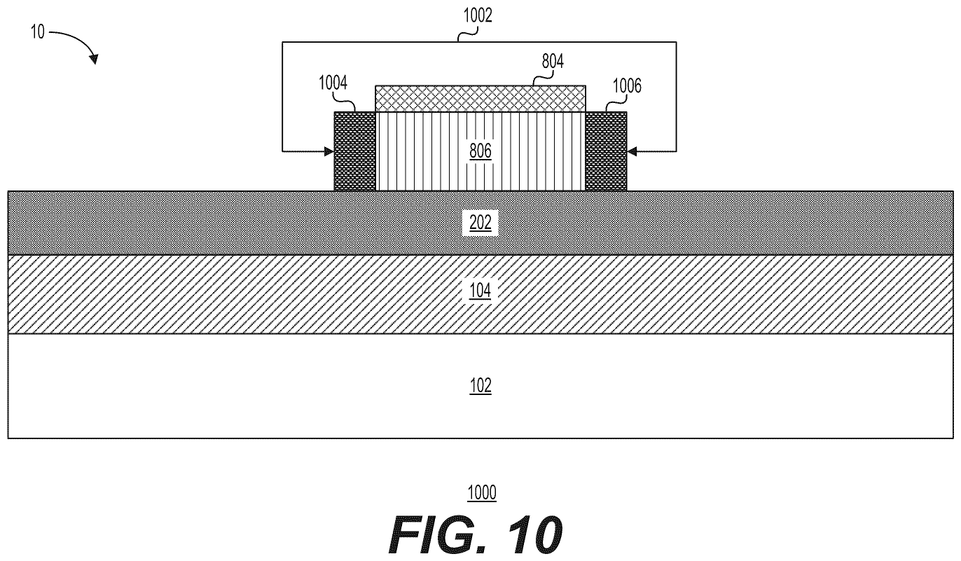

FIG. 10 shows a cross-section view 1000 of the semiconductor device 10 during a subsequent fabrication stage in accordance with one example. Unless expressly indicated otherwise, the same or similar regions and structures that are shown in FIG. 10 are referred to using the same reference numbers as used in FIGS. 1-9. As a result, such same or similar regions and structures are not described again as part of the description associated with FIG. 10. During this state of fabrication, hardmask 1002 is formed. Hardmask 1002 can be formed using at least one of two ways. One way relates to selective atomic layer deposition (ALD) of certain materials, including, for example, titanium nitride or aluminum dioxide, to form sidewalls 1004 and 1006 related to hardmask 1002. The ALD process can include sequential exposure of the exposed sides of the patterned sacrificial base layer 806 to a metal precursor and a reactant to deposit a metal film. In some embodiments, the metal precursor comprises a metal halide compound. As an example, metal halide precursor comprises a tungsten halide. The halogen can be any suitable halogen atoms and can be the same halogen or different halogens. As an example, the metal precursor can be a metal chloride, a metal fluoride, a metal bromide, a metal iodide or a metal atom with a mixture of fluorine, chlorine, bromine or iodine atoms. Selecting a precursor reactant that only adheres to the exposed sides of the patterned sacrificial based layer 806, the atomic deposition can be limited to the sidewall only. The ALD process can be either a time-domain process as part of which the precursor and the reactant species are not present in the ALD processing chamber at the same time. Alternatively, the ALD process can be a spatial process where the precursor and reactant are provided to different parts of the processing chamber that are isolated from each other in terms of the flow of the precursor and the reactant. Moreover, in the spatial ALD process, the substrate can be moved from a first process region with the metal precursor to a second process region with the reactant.

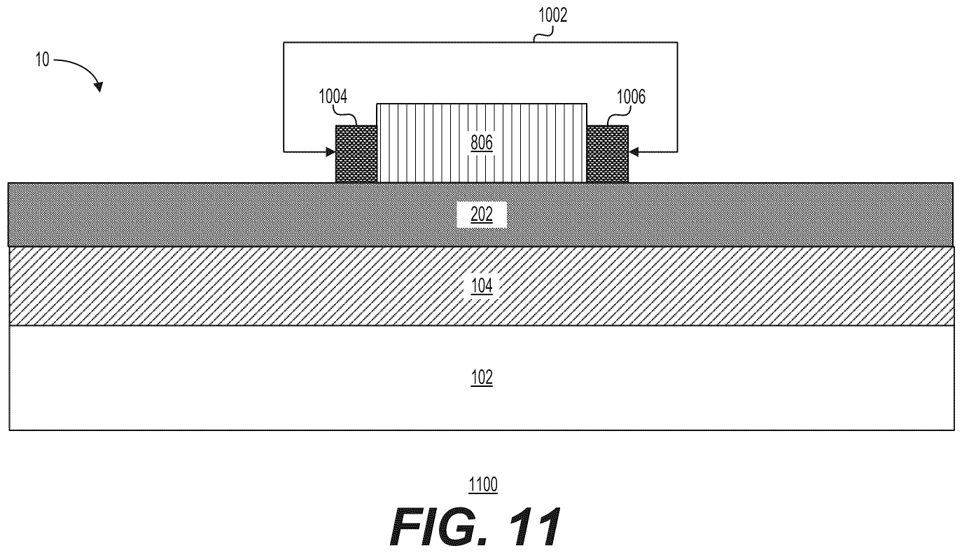

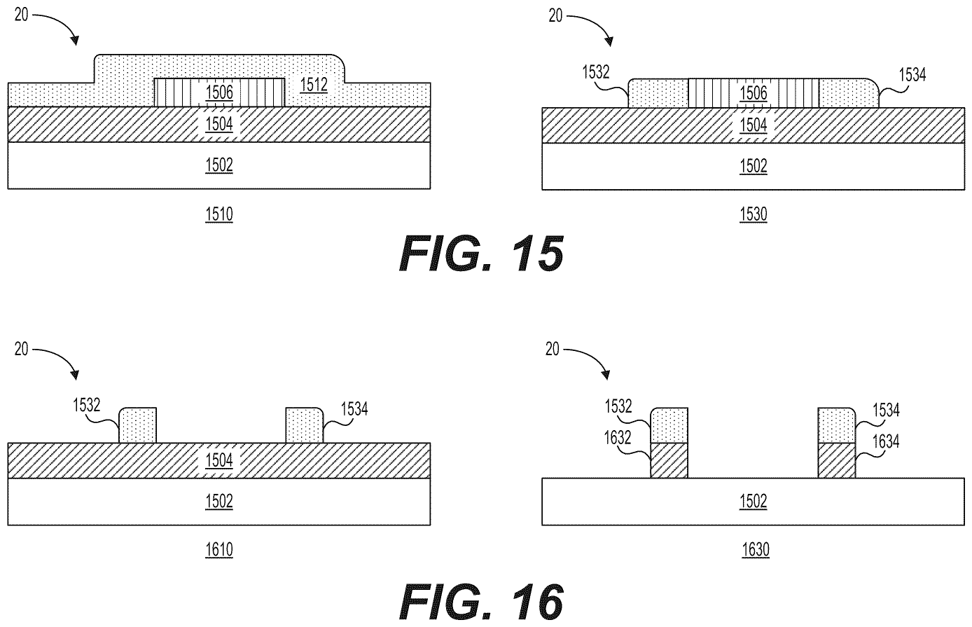

With continued reference to FIG. 10, another way to form hardmask 1002 is to grow sidewall layers 1004 and 1006 adjacent to each side of patterned sacrificial base layer 806. The formation of hardmask 1002 creates self-aligned double-patterned mask lines whose critical dimensions are defined by sidewall layer thickness. Advantageously, because the thickness of the sidewall layers is controlled by the film growth conditions or by atomic layer deposition, it has the potential to be thinner than the hardmasks created using spacer etch-back processes, such as described with respect to FIGS. 15 and 16. Specifically, FIG. 15 shows cross-section views 1510 and 1530 during fabrication of a semiconductor device 20 using a spacer etch-back process. Cross-section view 1510 shows a substrate 1502 with a target layer 1504 and a hardmask 1506. Cross-section view 1510 further shows a spacer 1512, which is formed over hardmask 1506 and target layer 1504. Cross-section view 1530 shows etching of spacer 1512 to form spacer sidewalls 1532 and 1534. FIG. 16 shows cross-section views 1610 and 1630 during subsequent stages of the fabrication of semiconductor device 20. Cross-section view 1610 shows the removal of hardmask 1506, leaving spacer sidewalls 1532 and 1534 in place. Cross-section view 1630 shows patterning of target layer 1504 using spacer sidewalls 1532 and 1534 to form features 1632 and 1634. As noted earlier, the use of spacers makes the critical dimensions subject to the limitations of the steps associated with spacer formation and spacer etch steps. Advantageously, the process steps described herein address these limitations as further detailed with respect to FIGS. 11, 14, and 17-19.

FIG. 11 shows a cross-section view 1100 of the semiconductor device 10 during a subsequent fabrication stage in accordance with one example. This stage follows the fabrication stage described earlier with cross-section view 1000 of FIG. 10. Unless expressly indicated otherwise, the same or similar regions and structures that are shown in FIG. 11 are referred to using the same reference numbers as used in FIGS. 1-10. As a result, such same or similar regions and structures are not described again as part of the description associated with FIG. 11. At this stage of the fabrication, patterned hardmask 804 is removed. Patterned hardmask 804 is removed by choosing an appropriate etch chemistry that results in the removal of patterned hardmask 804 while preventing the removal of a significant amount of hardmask 1002. By choosing appropriate etch chemistry and power (DC bias) applied, the loss of hardmask 1002 can be minimized. As an example, if patterned hardmask 804 is formed of silicon nitride (Si₃N₄) while hardmask 1002 is formed of aluminum oxide (Al₂O₃), the appropriate ratio of tetrafluoromethane (CF₄) (also known as carbon tetrafluoride) and hydrogen gases (H₂) can be selected. Similarly, the amount of plasma power can be selected to preferentially etch aluminum oxide (Al₂O₃). As another example, silicon nitride (Si₃N₄) can be selectively wet-etched using phosphoric acid (H₃PO₄).

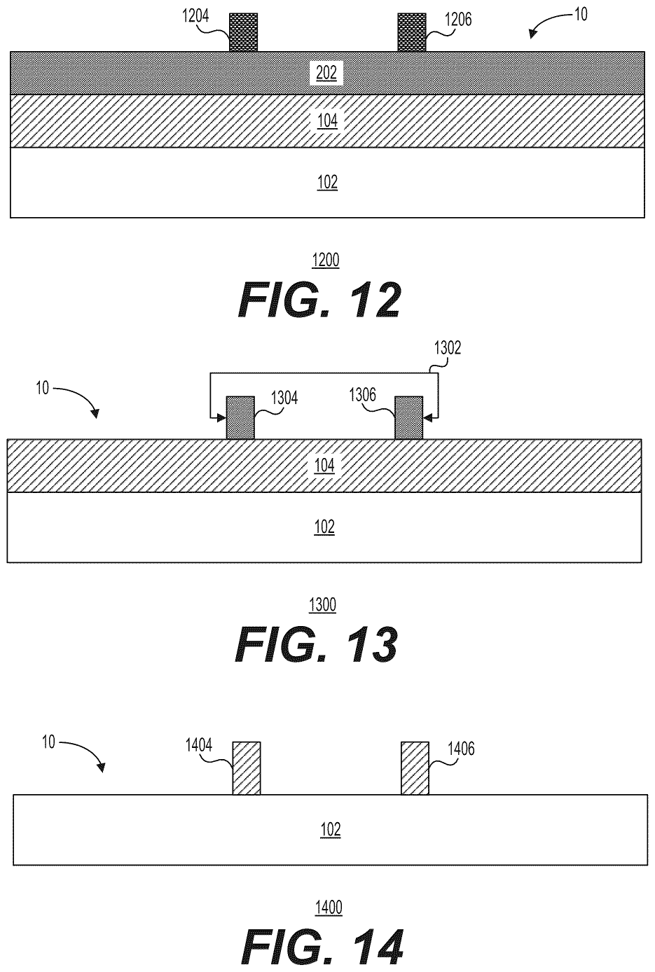

FIG. 12 shows a cross-section view 1200 of the semiconductor device 10 during a subsequent fabrication stage in accordance with one example. Unless expressly indicated otherwise, the same or similar regions and structures that are shown in FIG. 12 are referred to using the same reference numbers as used in FIGS. 1-11. As a result, such same or similar regions and structures are not described again as part of the description associated with FIG. 12. At this stage of the fabrication, patterned sacrificial base layer 806 is removed. Patterned sacrificial base layer 806 is removed by choosing an appropriate etch chemistry that results in the removal of patterned sacrificial base layer 806 while preventing the removal of a significant amount of hardmask 1002. By choosing appropriate etch chemistry and power (DC bias) applied, the loss of hardmask 1002 can be minimized. As an example, if patterned sacrificial base layer 806 is formed of silicon nitride (Si₃N₄) while hardmask 1002 is formed of aluminum oxide (Al₂O₃), the appropriate ratio of tetrafluoromethane (CF₄) (also known as carbon tetrafluoride) and hydrogen gases (H₂) can be selected. Similarly, the amount of plasma power can be selected to preferentially etch aluminum oxide (Al₂O₃). As another example, silicon nitride (Si₃N₄) can be selectively wet-etched using phosphoric acid (H₃PO₄). As shown in cross-section view 1200, semiconductor device 10 now includes remaining portions 1204 and 1206 of the patterned silicon base layer 806.

FIG. 13 shows a cross-section view 1300 of the semiconductor device 10 during a subsequent fabrication stage in accordance with one example. Unless expressly indicated otherwise, the same or similar regions and structures that are shown in FIG. 13 are referred to using the same reference numbers as used in FIGS. 1-12. As a result, such same or similar regions and structures are not described again as part of the description associated with FIG. 13. At this stage, portions 1202 and 1204 of the patterned silicon base layer 806 are used to pattern hardmask 202 resulting in patterned hardmask 1302 having portions 1304 and 1306. In this example, hardmask 202 is patterned using anisotropic etch processes. As an example, if hardmask 202 comprises silicon dioxide (SiO₂), then the trifluoro-methane (CHF₃) gas mixture may be appropriate. If, on the other hand, hardmask 202 comprises silicon nitride (Si₃N₄), then a gas mixture including an appropriate ratio of tetrafluoromethane (CF₄) (also known as carbon tetrafluoride) and hydrogen gases (H₂) can be selected. Indeed, the selection of the material used for forming the third hardmask 1002 also influences the gas chemistry selection. As shown in FIG. 14, the patterning of target layer 104 using anisotropic etch processes leaves the patterned target layer features 1404 and 1406 formed over substrate 102. The patterned target layer features 1404 and 1406 may correspond to various features of devices, such as transistors or other semiconductor devices or hybrid superconductor-semiconductor devices. The patterned target layer features 1404 and 1406 may also correspond to circuits formed as part of semiconductor devices or hybrid superconductor-semiconductor devices.

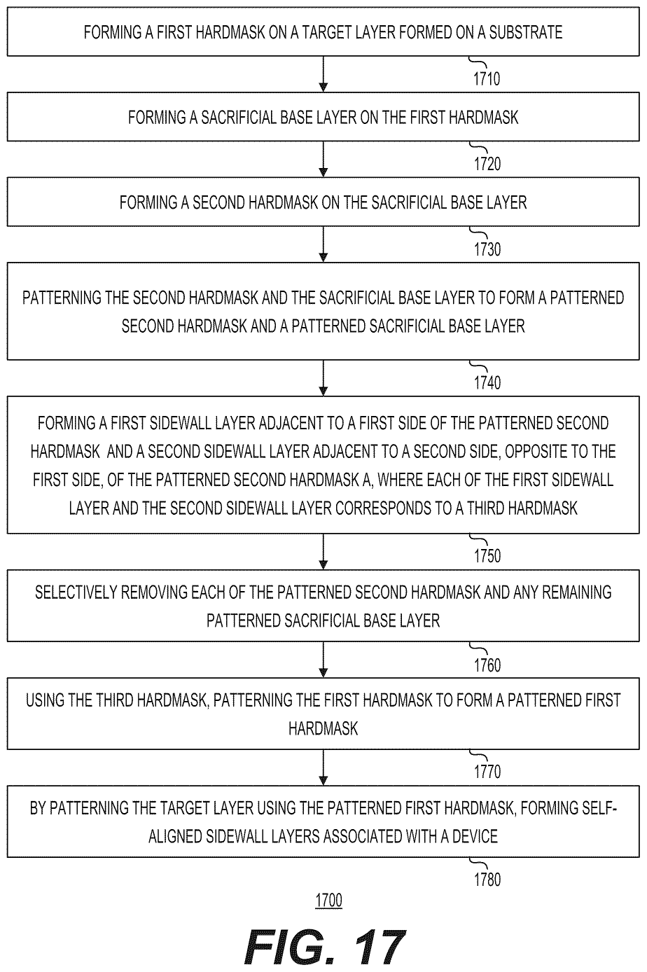

FIG. 17 shows a flowchart 1700 of a self-aligned double-patterning sidewall layer (SADP-SL) process for fabricating a device in accordance with one example. As used as part of this flowchart, the term “formed on” includes one of either formed directly on an underlying layer, or formed on one or more intermediate layers above the underlying layer. Step 1710 includes forming a first hardmask on a target layer formed on a substrate. In one example, this step may include the formation of the layers described with respect to FIGS. 1 and 2. As an example, target layer 104 of FIG. 1 is formed over substrate 102. Next, a hardmask 202 is formed on target layer 104 of FIG. 1. Step 1720 includes forming a sacrificial base layer over the first hardmask. As an example, sacrificial base layer 302 of FIG. 3 is formed as part of this step. Step 1730 includes forming a second hardmask on the sacrificial base layer. As an example, hardmask 402 is formed over the sacrificial base layer 302 as described earlier with respect to FIG. 4.

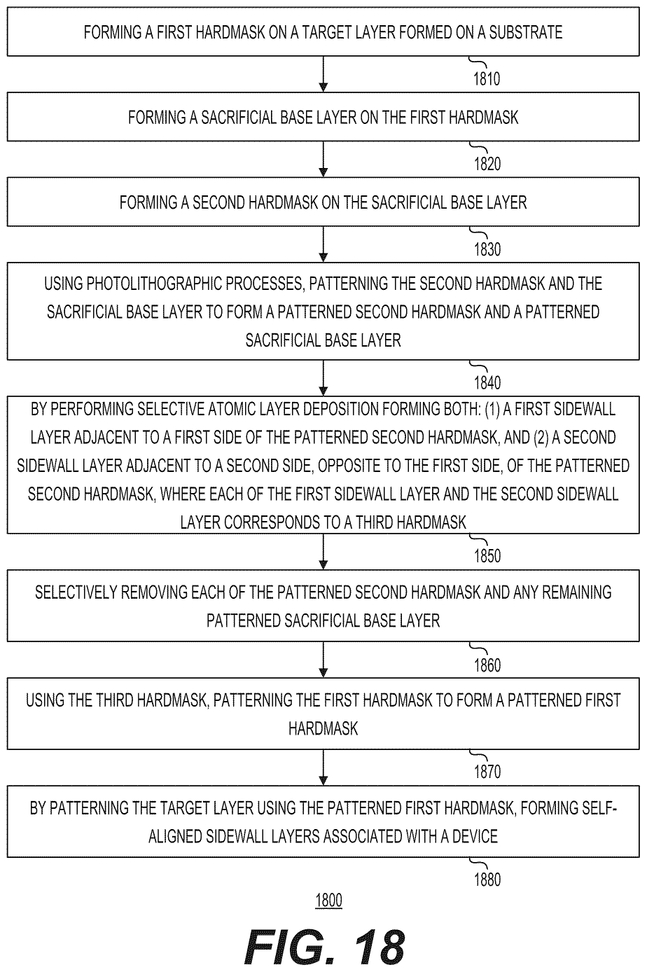

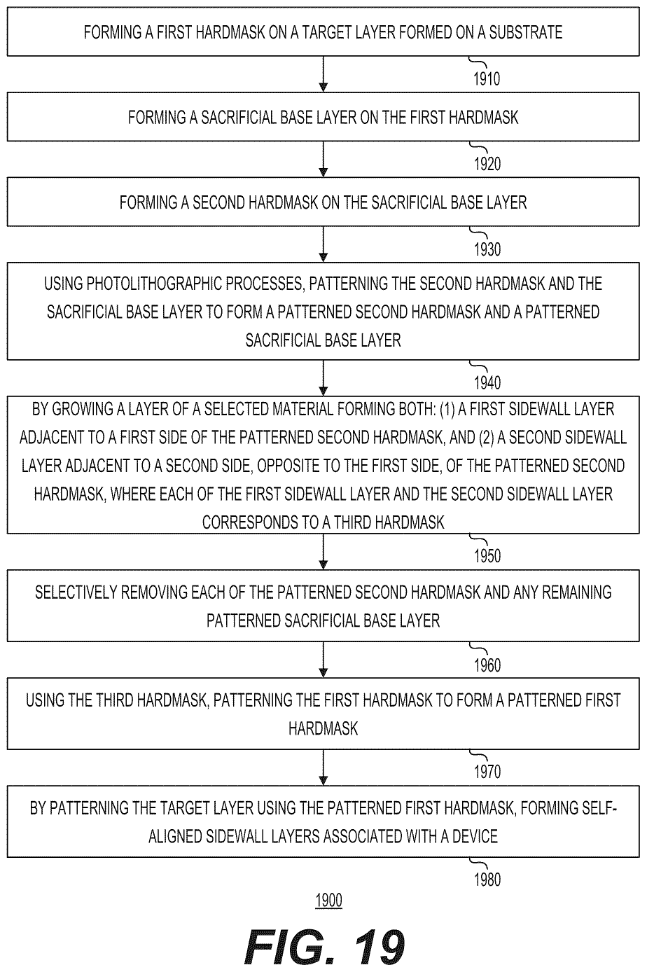

Step 1740 includes patterning the second hardmask and the sacrificial base layer to form a patterned second hardmask and a patterned sacrificial base layer. In one example, this step may include the process steps described earlier with respect to FIGS. 5-8. Step 1750 includes forming a first sidewall layer adjacent to a first side of the patterned second hardmask and a second sidewall layer adjacent to a second side, opposite to the first side, of the patterned second hardmask, where each of the first sidewall layer and the second sidewall layer corresponds to a third hardmask. As an example, the third hardmask corresponds to hardmask 1002 of FIG. 10, the first sidewall layer corresponds to sidewall layer 1004 of FIG. 10, and the second sidewall layer corresponds to sidewall layer 1006 of FIG. 10. As explained later with respect to FIGS. 18 and 19, the forming of the first sidewall layer and the second sidewall layer may include growing the first sidewall layer and the second sidewall layer adjacent to exposed areas of the patterned second hardmask. Alternatively, forming the first sidewall layer and the second sidewall layer may comprise performing selective atomic layer deposition.

Step 1760 includes selectively removing each of the patterned second hardmask and any remaining sacrificial base layer. As an example, FIGS. 11 and 12 show the removal of both patterned hardmask 804 and patterned sacrificial base layer 806. Step 1770 includes using the third hardmask, patterning the first hardmask to form a patterned first hardmask. As an example, FIG. 12 shows using the third hardmask, including sidewall layers 1204 and 1206 to pattern the first hardmask 202 (described earlier with respect to FIG. 2). Step 1780 includes by patterning the target layer using the patterned first hardmask, forming self-aligned sidewall layers associated with the device. As explained with respect to FIGS. 13 and 14, self-aligned sidewall layers 1404 and 1406 are formed by patterning the target layer (e.g., target layer 104 of FIG. 1). As an example, as part of this step, patterned hardmask 1302 is used.

FIG. 18 shows a flowchart 1800 of a self-aligned double-patterning sidewall layer (SADP-SL) process for fabricating a device in accordance with one example. As used as part of this flowchart, the term “formed on” includes one of either formed directly on an underlying layer, or formed on one or more intermediate layers above the underlying layer. Step 1810 includes forming a first hardmask on a target layer formed on a substrate. In one example, this step may include the formation of the layers described with respect to FIGS. 1 and 2. As an example, target layer 104 of FIG. 1 is formed over substrate 102. Next, a hardmask 202 is formed on target layer 104. Step 1820 includes forming a sacrificial base layer over the first hardmask. As an example, sacrificial base layer 302 of FIG. 3 is formed as part of this step. Step 1830 includes forming a second hardmask on the sacrificial base layer. As an example, hardmask 402 is formed over the sacrificial base layer 302 as described earlier with respect to FIG. 4.

Step 1840 includes using photolithographic processes, patterning the second hardmask and the sacrificial base layer to form a patterned second hardmask and a patterned sacrificial base layer. In one example, this step may include the process steps described earlier with respect to FIGS. 5-8. Step 1850 includes by performing selective atomic layer deposition forming both: (1) a first sidewall layer adjacent to a first side of the patterned second hardmask, and (2) a second sidewall layer adjacent to a second side, opposite to the first side, of the patterned second hardmask, where each of the first sidewall layer and the second sidewall layer corresponds to a third hardmask. As an example, the third hardmask corresponds to hardmask 1002 of FIG. 10, the first sidewall layer corresponds to sidewall layer 1004 of FIG. 10, and the second sidewall layer corresponds to sidewall layer 1006 of FIG. 10. As described in detail with respect to FIG. 14, performing the selective atomic layer deposition comprises using a precursor reactant that adheres to exposed areas of the patterned second hardmask, thereby limiting atomic deposition to only sidewalls of the patterned second hardmask.

Step 1860 includes selectively removing each of the patterned second hardmask and any remaining sacrificial base layer. As an example, FIGS. 11 and 12 show the removal of both patterned hardmask 804 and patterned sacrificial base layer 806. Step 1870 includes using the third hardmask, patterning the first hardmask to form a patterned first hardmask. As an example, FIG. 12 shows using the third hardmask, including sidewall layers 1204 and 1206 to pattern the first hardmask 202 (described earlier with respect to FIG. 2). Step 1880 includes by patterning the target layer using the patterned first hardmask, forming self-aligned sidewall layers associated with the device. As explained with respect to FIGS. 13 and 14, self-aligned sidewall layers 1404 and 1406 are formed by patterning the target layer (e.g., target layer 104 of FIG. 1). As an example, as part of this step, patterned hardmask 1302 is used.

FIG. 19 shows a flowchart 1900 of a self-aligned double-patterning sidewall layer (SADP-SL) process for fabricating a device in accordance with one example. As used as part of this flowchart, the term “formed on” includes one of either formed directly on an underlying layer, or formed on one or more intermediate layers above the underlying layer. Step 1910 includes forming a first hardmask on a target layer formed on a substrate. In one example, this step may include the formation of the layers described with respect to FIGS. 1 and 2. As an example, target layer 104 of FIG. 1 is formed over substrate 102. Next, a hardmask 202 is formed on target layer 104 of FIG. 1. Step 1920 includes forming a sacrificial base layer over the first hardmask. As an example, sacrificial base layer 302 of FIG. 3 is formed as part of this step. Step 1930 includes forming a second hardmask on the sacrificial base layer. As an example, hardmask 402 is formed over the sacrificial base layer 302 as described earlier with respect to FIG. 4.

Step 1940 includes using photolithographic processes, patterning the second hardmask and the sacrificial base layer to form a patterned second hardmask and a patterned sacrificial base layer. In one example, this step may include the process steps described earlier with respect to FIGS. 5-8. Step 1950 includes by growing a layer of a selected material forming both: (1) a first sidewall layer adjacent to a first side of the patterned second hardmask, and (2) a second sidewall layer adjacent to a second side, opposite to the first side, of the patterned second hardmask, where each of the first sidewall layer and the second sidewall layer corresponds to a third hardmask. As an example, the third hardmask corresponds to hardmask 1002 of FIG. 10, the first sidewall layer corresponds to sidewall layer 1004 of FIG. 10, and the second sidewall layer corresponds to sidewall layer 1006 of FIG. 10. As described earlier with respect to FIG. 14, growing the selected layer of the material comprises growing the first sidewall layer and the second sidewall layer adjacent to exposed areas of the patterned second hardmask.

Step 1960 includes selectively removing each of the patterned second hardmask and any remaining sacrificial base layer. As an example, FIGS. 11 and 12 show the removal of both patterned hardmask 804 and patterned sacrificial base layer 806. Step 1970 includes using the third hardmask, patterning the first hardmask to form a patterned first hardmask. As an example, FIG. 12 shows using the third hardmask, including sidewall layers 1204 and 1206 to pattern the first hardmask 202 (described earlier with respect to FIG. 2). Step 1980 includes by patterning the target layer using the patterned first hardmask, forming self-aligned sidewall layers associated with the device. As explained with respect to FIGS. 13 and 14, self-aligned sidewall layers 1404 and 1406 are formed by patterning the target layer (e.g., target layer 104 of FIG. 1). As an example, as part of this step, patterned hardmask 1302 is used.

In conclusion, the present disclosure relates to a self-aligned double-patterning sidewall layer (SADP-SL) process for fabricating a device. The (SADP-SL) process may include forming a first hardmask on a target layer formed on a substrate. The (SADP-SL) process may further include forming a sacrificial base layer on the first hardmask. The (SADP-SL) process may further include forming a second hardmask on the sacrificial base layer. The (SADP-SL) process may further include patterning the second hardmask and the sacrificial base layer to form a patterned second hardmask and a patterned sacrificial base layer.

The (SADP-SL) process may further include forming a first sidewall layer adjacent to a first side of the patterned second hardmask and a second sidewall layer adjacent to a second side, opposite to the first side, of the patterned second hardmask, where each of the first sidewall layer and the second sidewall layer corresponds to a third hardmask. The (SADP-SL) process may further include selectively removing each of the patterned second hardmask and any remaining patterned sacrificial base layer. The (SADP-SL) process may further include using the third hardmask, patterning the first hardmask to form a patterned first hardmask. The (SADP-SL) process may further include by patterning the target layer using the patterned first hardmask, forming self-aligned sidewall layers associated with the device.

The SADP-SL process may further include patterning the second hardmask and the sacrificial base layer to form a patterned second hardmask and a patterned sacrificial base layer comprises using photolithographic processes. Forming the first sidewall layer and the second sidewall layer may comprise growing the first sidewall layer and the second sidewall layer adjacent to exposed areas of the patterned second hardmask. Alternatively, forming the first sidewall layer and the second sidewall layer may comprise performing selective atomic layer deposition.

Performing selective atomic layer deposition may comprise using a precursor reactant that adheres to exposed areas of the patterned second hardmask, thereby limiting atomic deposition to only sidewalls of the patterned second hardmask. Selectively removing each of the patterned second hardmask and any remaining patterned sacrificial base layer may comprise selecting an etch chemistry to minimize loss of any material associated with the third hardmask. Selectively removing each of the patterned second hardmask and any remaining patterned sacrificial base layer may further comprise using a selected amount of power to further minimize the loss of any material associated with the third hardmask. By patterning the target layer using the patterned first hardmask, one may form the self-aligned sidewall layers associated with the device comprises using anisotropic etch processes.

In another aspect, the present disclosure relates to a self-aligned double-patterning sidewall layer (SADP-SL) process for fabricating a device. The (SADP-SL) process may include forming a first hardmask on a target layer formed on a substrate. The (SADP-SL) process may further include forming a sacrificial base layer on the first hardmask. The (SADP-SL) process may further include forming a second hardmask on the sacrificial base layer. The (SADP-SL) process may further include patterning the second hardmask and the sacrificial base layer to form a patterned second hardmask and a patterned sacrificial base layer.

The (SADP-SL) process may further include by performing selective atomic layer deposition forming both: (1) a first sidewall layer adjacent to a first side of the patterned second hardmask, and (2) a second sidewall layer adjacent to a second side, opposite to the first side, of the patterned second hardmask, where each of the first sidewall layer and the second sidewall layer corresponds to a third hardmask. The (SADP-SL) process may further include selectively removing each of the patterned second hardmask and any remaining patterned sacrificial base layer. The (SADP-SL) process may further include using the third hardmask, patterning the first hardmask to form a patterned first hardmask. The (SADP-SL) process may further include by patterning the target layer using the patterned first hardmask, forming self-aligned sidewall layers associated with the device.

Performing selective atomic layer deposition may comprise using a precursor reactant that adheres to exposed areas of the patterned second hardmask, thereby limiting atomic deposition to only sidewalls of the patterned second hardmask. Selectively removing each of the patterned second hardmask and any remaining patterned sacrificial base layer may comprise selecting an etch chemistry to minimize loss of any material associated with the third hardmask. Selectively removing each of the patterned second hardmask and any remaining patterned sacrificial base layer may further comprise using a selected amount of power to further minimize the loss of any material associated with the third hardmask.

As part of the (SADP-SL) process, by patterning the target layer using the patterned first hardmask, one may form the self-aligned sidewall layers associated with the device comprises using anisotropic etch processes. The third mask may comprise a self-aligned double-patterned mask whose critical dimensions are defined by a thickness of each of the first sidewall layer and the second sidewall layer.

In yet another aspect, the present disclosure relates to a self-aligned double-patterning sidewall layer (SADP-SL) process for fabricating a device. The (SADP-SL) process may include forming a first hardmask on a target layer formed on a substrate. The (SADP-SL) process may further include forming a sacrificial base layer on the first hardmask. The (SADP-SL) process may further include forming a second hardmask on the sacrificial base layer. The (SADP-SL) process may further include patterning the second hardmask and the sacrificial base layer to form a patterned second hardmask and a patterned sacrificial base layer.

The (SADP-SL) process may further include by growing a layer of a selected material forming both: (1) a first sidewall layer adjacent to a first side of the patterned second hardmask, and (2) a second sidewall layer adjacent to a second side, opposite to the first side, of the patterned second hardmask, where each of the first sidewall layer and the second sidewall layer corresponds to a third hardmask. The (SADP-SL) process may further include selectively removing each of the patterned second hardmask and any remaining patterned sacrificial base layer. The (SADP-SL) process may further include using the third hardmask, patterning the first hardmask to form a patterned first hardmask. The (SADP-SL) process may further include by patterning the target layer using the patterned first hardmask, forming self-aligned sidewall layers associated with the device.

Growing the selected layer of the material may comprise growing the first sidewall layer and the second sidewall layer adjacent to exposed areas of the patterned second hardmask. Growing the selected layer of the material comprises growing successive layers of the material. Selectively removing each of the patterned second hardmask and any remaining patterned sacrificial base layer may comprise selecting an etch chemistry to minimize loss of any material associated with the third hardmask. Selectively removing each of the patterned second hardmask and any remaining patterned sacrificial base layer may further comprise using a selected amount of power to further minimize the loss of any material associated with the third hardmask. As part of the (SADP-SL) process, by patterning the target layer using the patterned first hardmask, one may form the self-aligned sidewall layers associated with the device comprises using anisotropic etch processes.

It is to be understood that the processes, methods, modules, and components depicted herein are merely exemplary. Although the formation of the semiconductor devices has been described with respect to specific conductivity types or polarity of potentials, skilled artisans appreciated that conductivity types and polarities of potentials may be reversed. Moreover, the terms “front,” “back,” “top,” “bottom,” “over,” “under” and the like in the description and in the claims, if any, are used for descriptive purposes and not necessarily for describing the only possible relative positions. It is to be understood that the terms so used are interchangeable under appropriate circumstances such that the examples described herein are, for example, capable of operation in other orientations than those illustrated or otherwise described herein.

In addition, in an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,” or “coupled,” to each other to achieve the desired functionality.

Furthermore, those skilled in the art will recognize that boundaries between the functionality of the above-described layers or components included in a device are merely illustrative. The functionality of multiple layers may be combined into a single layer, and/or the functionality of a single layer may be distributed in additional layers. Moreover, alternative embodiments may include multiple instances of a particular layer, and the order of layers (e.g., from top to bottom or bottom to top) may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed:

1. A self-aligned double-patterning sidewall layer (SADP-SL) process for fabricating a device comprising:
forming a first hardmask on a target layer formed on a substrate;
forming a sacrificial base layer on the first hardmask;
forming a second hardmask on the sacrificial base layer;
patterning the second hardmask and the sacrificial base layer to form a patterned second hardmask and a patterned sacrificial base layer;
forming a first sidewall layer adjacent to a first side of the patterned second hardmask and a second sidewall layer adjacent to a second side, opposite to the first side, of the patterned second hardmask, wherein each of the first sidewall layer and the second sidewall layer corresponds to a third hardmask;
selectively removing each of the patterned second hardmask and any remaining patterned sacrificial base layer;
using the third hardmask, patterning the first hardmask to form a patterned first hardmask; and
by patterning the target layer using the patterned first hardmask, forming self-aligned sidewall layers associated with the device.

2. The SADP-SL process of claim 1, patterning the second hardmask and the sacrificial base layer to form a patterned second hardmask and a patterned sacrificial base layer comprises using photolithographic processes.

3. The SADP-SL process of claim 1, wherein forming the first sidewall layer and the second sidewall layer comprises growing the first sidewall layer and the second sidewall layer adjacent to exposed areas of the patterned second hardmask.

4. The SADP-SL process of claim 1, wherein forming the first sidewall layer and the second sidewall layer comprises performing selective atomic layer deposition.

5. The SADP-SL process of claim 4, wherein performing selective atomic layer deposition comprises using a precursor reactant that adheres to exposed areas of the patterned second hardmask, thereby limiting atomic deposition to only sidewalls of the patterned second hardmask.

6. The SADP-SL process of claim 1, wherein selectively removing each of the patterned second hardmask and any remaining patterned sacrificial base layer comprises selecting an etch chemistry to minimize loss of any material associated with the third hardmask.

7. The SADP-SL process of claim 6, wherein selectively removing each of the patterned second hardmask and any remaining patterned sacrificial base layer further comprises using a selected amount of power to further minimize the loss of any material associated with the third hardmask.

8. The SADP-SL process of claim 1, wherein by patterning the target layer using the patterned first hardmask, forming the self-aligned sidewall layers associated with the device comprises using anisotropic etch processes.

9. A self-aligned double-patterning sidewall layer (SADP-SL) process for fabricating a device comprising:
forming a first hardmask on a target layer formed on a substrate;
forming a sacrificial base layer on the first hardmask;
forming a second hardmask on the sacrificial base layer;
using photolithographic processes, patterning the second hardmask and the sacrificial base layer to form a patterned second hardmask and a patterned sacrificial base layer;
by performing selective atomic layer deposition forming both: (1) a first sidewall layer adjacent to a first side of the patterned second hardmask, and (2) a second sidewall layer adjacent to a second side, opposite to the first side, of the patterned second hardmask, wherein each of the first sidewall layer and the second sidewall layer corresponds to a third hardmask;
selectively removing each of the patterned second hardmask and any remaining patterned sacrificial base layer;
using the third hardmask, patterning the first hardmask to form a patterned first hardmask; and
by patterning the target layer using the patterned first hardmask, forming self-aligned sidewall layers associated with the device.

10. The SADP-SL process of claim 9, wherein performing selective atomic layer deposition comprises using a precursor reactant that adheres to exposed areas of the patterned second hardmask, thereby limiting atomic deposition to only sidewalls of the patterned second hardmask.

11. The SADP-SL process of claim 9, wherein selectively removing each of the patterned second hardmask and any remaining patterned sacrificial base layer comprises selecting an etch chemistry to minimize loss of any material associated with the third hardmask.

12. The SADP-SL process of claim 11, wherein selectively removing each of the patterned second hardmask and any remaining patterned sacrificial base layer further comprises using a selected amount of power to further minimize the loss of any material associated with the third hardmask.

13. The SADP-SL process of claim 9, wherein by patterning the target layer using the patterned first hardmask, forming the self-aligned sidewall layers associated with the device comprises using anisotropic etch processes.

14. The SADP-SL process of claim 9, wherein the third mask comprises a self-aligned double-patterned mask whose critical dimensions are defined by a thickness of each of the first sidewall layer and the second sidewall layer.

15. A self-aligned double-patterning sidewall layer (SADP-SL) process for fabricating a device comprising:
forming a first hardmask on a target layer formed on a substrate;
forming a sacrificial base layer on the first hardmask;
forming a second hardmask on the sacrificial base layer;
using photolithographic processes, patterning the second hardmask and the sacrificial base layer to form a patterned second hardmask and a patterned sacrificial base layer;
by growing a layer of a selected material forming both: (1) a first sidewall layer adjacent to a first side of the patterned second hardmask, and (2) a second sidewall layer adjacent to a second side, opposite to the first side, of the patterned second hardmask, wherein each of the first sidewall layer and the second sidewall layer corresponds to a third hardmask;
selectively removing each of the patterned second hardmask and any remaining patterned sacrificial base layer;
using the third hardmask, patterning the first hardmask to form a patterned first hardmask; and
by patterning the target layer using the patterned first hardmask, forming self-aligned sidewall layers associated with the device.

16. The SADP-SL process of claim 15, wherein growing the selected layer of the material comprises growing the first sidewall layer and the second sidewall layer adjacent to exposed areas of the patterned second hardmask.

17. The SADP-SL process of claim 15, wherein growing the selected layer of the material comprises growing successive layers of the material.

18. The SADP-SL process of claim 15, wherein selectively removing each of the patterned second hardmask and any remaining patterned sacrificial base layer comprises selecting an etch chemistry to minimize loss of any material associated with the third hardmask.

19. The SADP-SL process of claim 18, wherein selectively removing each of the patterned second hardmask and any remaining patterned sacrificial base layer further comprises using a selected amount of power to further minimize the loss of any material associated with the third hardmask.

20. The SADP-SL process of claim 15, wherein by patterning the target layer using the patterned first hardmask, forming the self-aligned sidewall layers associated with the device comprises using anisotropic etch processes.
